(19) United States
(12) Patent Application Publication
(10) Pub. No.: US 2012/0125679 A1
(43) Pub. Date: May 24, 2012

(54) PRINTED CIRCUIT BOARD HAVING DIFFERENTIAL VIAS

(75) Inventors: YUNG-CHIEH CHEN, Tu-Cheng (TW); CHENG-HSIEN LEE, Tu-Cheng (TW); PO-CHUAN HSIEH, Tu-Cheng (TW); SHOU-KUO HSU, Tu-Cheng (TW); SHIN-TING YEN, Tu-Cheng (TW)

(73) Assignee: HON HAI PRECISION INDUSTRY CO., LTD., Tu-Cheng (TW)

(21) Appl. No.: 13/032,653

(22) Filed: Feb. 23, 2011

(30) Foreign Application Priority Data
Nov. 23, 2010 (TW) 99140273

(51) Int. Cl. H05K 1/11

(52) U.S. Cl. 174/266

(57) ABSTRACT

A printed circuit board includes an insulating board, a pair of differential vias, and a number of wiring layers. A pair of via holes extends through opposite surfaces of the insulating board. The differential vias correspond to the pair of via holes. Each differential via includes a metal plated barrel and two via capture pads. The plated barrel is plated on the inner surface of the respective via hole, and terminates at each of the two opposite surfaces of the insulating board. The via capture pads are formed on the opposite surfaces of the insulating board around the openings of the via hole, and are electrically connected to the plated barrel. The wiring layers are arranged in the insulating board, and each define a clearance hole surrounding all of the via capture pads.

### BACKGROUND

1. Technical Field

The present disclosure relates to printed circuit boards (PCBs), and more especially, to a printed circuit board having a pair of differential vias.

2. Description of Related Art

Signal integrity is an important factor to be taken into account when a printed circuit board (PCB) is designed. Proper signal integrity helps the PCB and an associated computer system to achieve stable performance.

For differential vias and associated transmission lines, characteristic impedances of the differential vias need to equal or approach characteristic impedances of the differential transmission lines. A pair of differential transmission lines laid on the PCB includes two transmission lines having a same length, and transmitting signals in mutually opposite directions. Differential transmission lines laid on two opposite surfaces of the PCB can be connected by differential vias. Typically, the characteristic impedance of the differential vias is twelve percent less than the characteristic impedance of the differential transmission lines connected to the vias. Because the characteristic impedances of the differential vias do not match the characteristic impedances of the differential transmission lines, signals arriving at the differential vias are apt to be partially reflected and cause a waveform of the signals to distort, overshoot, or undershoot. Thus, the differential vias may reduce the quality of the signals passed by the differential vias and the differential transmission lines.

What is needed, therefore, is a PCB having a pair of differential vias, to overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a schematic, front view of a PCB having a pair of differential vias in accordance with a first exemplary embodiment.

FIG. 2 is a sectional view of the PCB of FIG. 1, taken along line II-II and showing multiple layers of the PCB.

FIG. 3 is a schematic, front view of a PCB having a pair of differential vias in accordance with a second exemplary embodiment.

### DETAILED DESCRIPTION

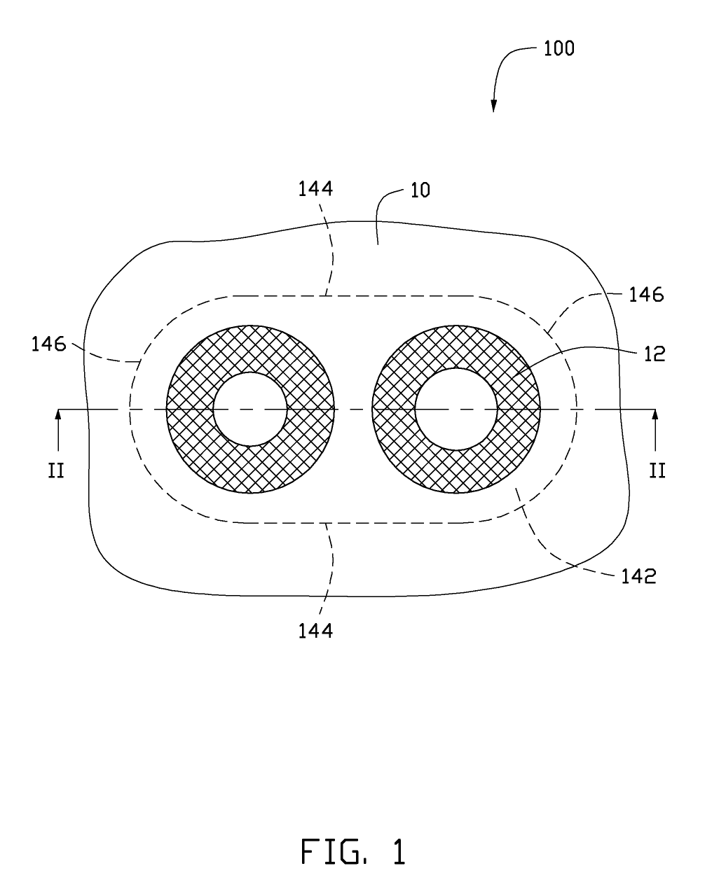

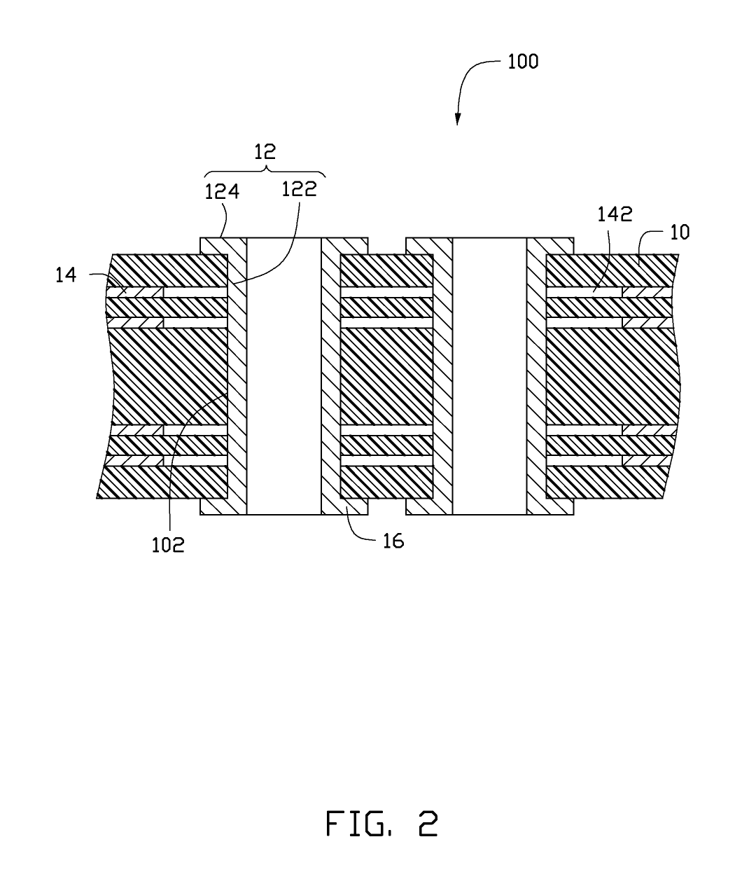

Referring to FIGS. 1 and 2, a PCB 100 in accordance with a first exemplary embodiment includes an insulating board 10, a pair of differential vias 12, and a plurality of wiring layers 14.

The insulating board 10 defines a pair of via holes 102 extending through the insulating board 10. Each of the via holes 102 is plated with metal, such as copper, to form a cylindrical plated barrel 122 along the wall surface of the via hole 102. The plated barrel 122 terminates at each of two opposite surfaces of the insulating board 10. Two via capture pads 124 are formed on the two opposite surfaces of the insulating board 10 around two opposite openings of each via hole 102. The via capture pads 124 are electrically connected to the respective plated barrel 122. In this embodiment, the via capture pads 124 are annular and aligned with the respective plated barrel 122. The via capture pads 124 and the respective plated barrels 122 cooperatively form the pair of differential vias 12.

Each of the wiring layers 14 defines a clearance hole 142 in the wiring layer 14. That is, each clearance hole 142 defined in the wiring layers 14 is hollow and allows the plated barrels 122 to pass through. In this embodiment, the clearance holes 142 are oval shaped and have two opposite straight edges 144 parallel to an imaginary line connecting the central axes of the via holes 122, and two arc-shaped edges 146 each interconnecting the straight edges 144 with each other. The two opposite parallel edges 144 are farther apart than an outer diameter of each via capture pad 124, and the arc-shaped edges 146 are spaced apart from the respective via capture pads 124, such that the via capture pads 124 are arranged within the clearance hole 142. Preferably, the via capture pads 124 are located symmetrically with respect to a center axis of the clearance hole 142.

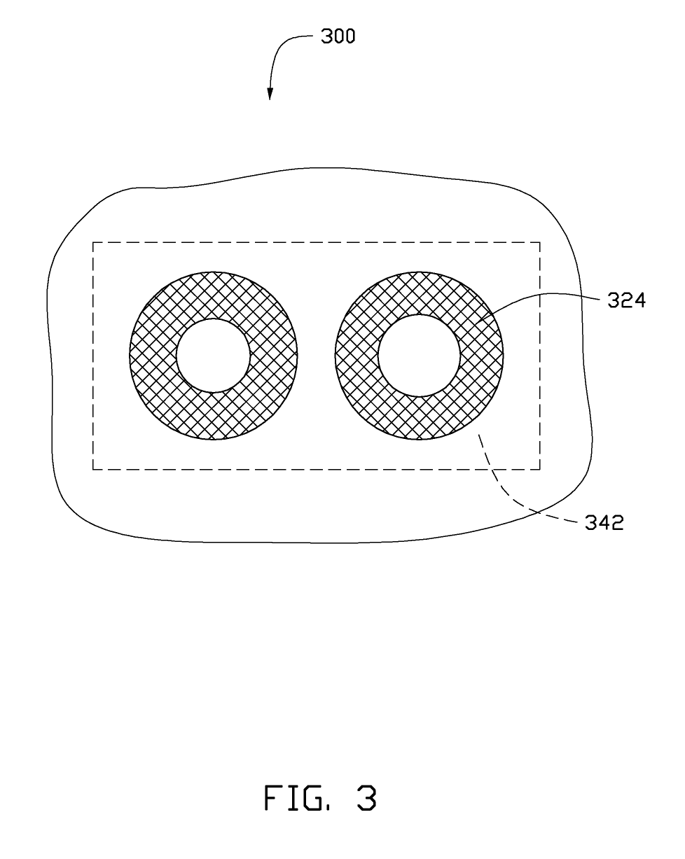

Referring to FIG. 3, a PCB 300 in accordance with a second exemplary embodiment is similar to the PCB 100, except that the PCB 300 has a clearance hole 342 in each of the wiring layers (not shown). The clearance hole 342 is different from the clearance hole 142 in that the clearance hole 342 has a rectangular shape surrounding the pair of via capture pads 324. Preferably, the via capture pads 324 are located symmetrically with respect to a center axis of the clearance holes 342.

In alternative embodiments, the clearance holes 342 can be other shapes.

In the first and second embodiments, there is no metal plating on the wiring layers 14 in the area of the via capture pads 124 and 324 and between the pair of differential vias 12. Thus, tolerance to external noise of the pair of differential vias 12 can be increased. The reflection of the signals between the differential transmission lines (not shown) and the differential vias 12 is minimized. Hence, the degradation of the signal at the pair of differential vias 12 can be efficiently decreased.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A printed circuit board, comprising:
an insulating board having a pair of via holes, the pair of via holes extending through opposite surfaces of the insulating board;
a pair of differential vias corresponding to the pair of via holes, each differential via comprising a metal plated barrel, and two via capture pads, the plated barrel being plated on the inner surface of the respective via hole and terminating at each of the two opposite surfaces of the insulating board, the via capture pads being formed on the opposite surfaces of the insulating board around the openings of the via hole, and electrically connected to the plated barrel; and
a plurality of wiring layers arranged in the insulating board, the wiring layers each defining a clearance hole surrounding all of the via capture pads.

2. The printed circuit board of claim 1, wherein the via capture pads are annular and aligned with the respective plated barrel.

3. The printed circuit board of claim 1, wherein the clearance hole is oval shaped in the front view of the insulating board, and the long circle shape has two straight parallel edges, and two arc-shaped edges interconnecting the two straight parallel edges with each other.

4. The printed circuit board of claim 3, wherein the two straight parallel edges are parallel to an imaginary line connecting the central axes of the via holes.

5. The printed circuit board of claim 4, wherein the via capture pads are located symmetrically with respect to a center axis of the clearance hole.

6. The printed circuit board of claim 1, wherein clearance hole is rectangular in the front view of the insulating board.

7. The printed circuit board of claim 6, wherein via capture pads are located symmetrically with respect to a center axis of the clearance hole.
